(19) United States
(12) Patent Application Publication
(10) Pub. No.: US 2023/0176107 A1
(43) Pub. Date: Jun. 8, 2023

(54) TESTING APPARATUS AND TESTING METHOD FOR A/D CONVERTER

(71) Applicant: ROHM CO., LTD., Kyoto-shi (JP)

(72) Inventor: Keno SATO, Kyoto-shi (JP)

(21) Appl. No.: 18/075,613

(22) Filed: Dec. 6, 2022

(30) Foreign Application Priority Data
Dec. 7, 2021 (JP) 2021-198642
Sep. 30, 2022 (JP) 2022-158679

(51) Int. Cl. G01R 31/26; H03M 1/10

(52) U.S. Cl. CPC G01R 31/2601; H03M 1/1071

(57) ABSTRACT

Provided is a method for testing a semiconductor device having an A/D converter, the method includes supplying a sinusoidal analog test signal S1 to an A/D converter, storing a group S2 of output codes generated by the A/D converter over a period with an integer K multiple duration of the cycle of the sine wave, in response to the analog test signal S1, and generating a histogram of the stored group S2 of the output codes, and evaluating the A/D converter on the basis of the histogram.

### CROSS REFERENCE TO RELATED APPLICATIONS

The present invention claims priority under 35 U.S.C. § 119 to Japanese Application No. 2021-198642, filed on Dec. 7, 2021, and Japanese Application No. 2022-158679, filed on Sep. 30, 2022, the entire contents of which are incorporated herein by reference.

### BACKGROUND

### 1. Technical Field

The present disclosure relates to an evaluation technique for A/D converter.

### 2. Description of the Related Art

A/D converter is one of key devices in a system that performs digital signal processing. Known indices for indicating performance of the A/D converter include differential non-linearity (DNL) and integral non-linearity (INL).

The A/D converter, or a chip or a system having the A/D converter incorporated therein needs to be inspected before shipment. Typically, an analog test signal having a sweep waveform across the entire code is input to an input terminal of the A/D converter, and an output in response thereto is measured. Now, the time required for the measurement is proportional to a product of a total number of the codes and a sampling time.

The analog test signal used for testing the A/D converter is a linear ramp signal whose voltage linearly changes. Some of the A/D converters have very slow sampling rate. For example, some of the A/D converters making use of a ΔΣ modulator have a sampling rate of only several samples per second (sps). Testing, for example, of a 24-bit A/D converter with a sampling rate of 6.8 sps takes as long as 685 hours to test all codes, which is not realistic.

Sinusoidal histogram method is a known method for evaluating the A/D converter. The method is designed to input a sinusoidal analog test signal to the A/D converter, to obtain a histogram of a group of the output codes acquired in response thereto, and to evaluate the DNL and INL on the basis of the histogram.

### SUMMARY

One embodiment of the present disclosure has been made in such circumstances, and a general purpose thereof is to provide a modified sinusoidal histogram method.

A testing apparatus according to one embodiment of the present disclosure is structured to test a semiconductor device having an A/D converter. The testing apparatus has a waveform generator structured to supply an analog test signal that contains a sine wave with a cycle of T, to the A/D converter; a waveform acquisition unit structured to store a group of output codes generated by the A/D converter, over a period with an integer K multiple duration of the cycle T, in response to the analog test signal; and an evaluation device structured to generate a histogram of the group of output codes stored by the waveform acquisition unit, and to evaluate the A/D converter on the basis of the histogram.

Also another embodiment of the present disclosure relates to a testing apparatus for testing a semiconductor device having an A/D converter. The testing apparatus includes: a waveform generator structured to supply a periodic analog test signal that contains a sine wave to the A/D converter; a waveform acquisition unit structured to store a group of output codes generated by the A/D converter, over a period with an integer K multiple duration of the cycle of the analog test signal, in response to the analog test signal; and an evaluation device structured to generate a histogram of the group of the output codes acquired by the waveform acquisition unit, and to evaluate the A/D converter on the basis of the histogram. Letting the count of a certain code i be P_{[i]}, the evaluation device is structured to acquire a count P_{[x]} of a minimum code x and a count P_{[y}] of a maximum code y, to detect, if P_{[x]}>P_{[y]}, a code z which gives an integrated value, over a section ranging from z to y in the histogram, closest to P_{[x]}, and to determine a midpoint between x and z as an offset q of the sine wave.

Still another embodiment of the present disclosure relates to a testing method for testing a semiconductor device having an A/D converter. The testing method includes: supplying an analog test signal that contains a sine wave and a cycle T, to the A/D converter; storing a group of output codes generated by the A/D converter, over a period with an integer K multiple duration of the cycle T, in response to the analog test signal; and generating a histogram of the stored group of output codes, and evaluating the A/D converter on the basis of the histogram.

Also still another embodiment of the present disclosure relates to a testing method for testing a semiconductor device having an A/D converter. The testing method includes: supplying a periodic analog test signal to the A/D converter; storing a group of output codes generated by the A/D converter, over a period with an integer K multiple duration of the cycle of the analog test signal, in response to the analog test signal; and generating a histogram of the stored group of output codes, and evaluating the A/D converter on the basis of the histogram. Let the count of a certain code i be P_{[i]}. The evaluation step is structured to acquire a count P_{[x]} of a minimum code x and a count P_{[y]} of a maximum code y, to detect, if P_{[x]}>P_{[y]}, a code z which gives an integrated value, over a section ranging from z to y in the histogram, closest to P_{[x]}, and to determine a midpoint between x and z as an offset q of the sine wave.

Note that also free combinations of these constituents, and also any of the constituents and expressions exchanged among the method, apparatus and system, are valid as the embodiments of the present invention. Furthermore, the description of this section (SUMMARY) does not describe all essential features of the invention, and thus subcombinations of these features described may also be the invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram illustrating a testing apparatus of an embodiment.

FIG. 2 is a drawing explaining a test of an A/D converter with use of the testing apparatus illustrated in FIG. 1.

FIG. 3 is a drawing illustrating a sine wave.

FIG. 4 is a drawing illustrating an amplitude probability density function p(V) of the sine wave illustrated in FIG. 3.

FIG. 5 is a drawing illustrating a relationship between the sine wave and a histogram.

FIG. 6 is a drawing illustrating results of simulation of the histogram, DNL, and INL.

FIG. 7 is a drawing illustrating a relationships between a full scale FS of the A/D converter and voltage levels of analog test signals.

FIG. 8 is a drawing illustrating histograms obtainable under a non-ideal condition.

FIG. 9 is a drawing illustrating a histogram obtainable under another non-ideal condition.

FIG. 10 is a drawing illustrating histograms obtainable at the numbers of cycles K of 1050 and 1049.

FIG. 11 is a drawing illustrating theoretical DNL and INL at the numbers of cycles K of 1049 and 1050.

FIG. 12 is a drawing illustrating theoretical DNL and INL at the numbers of cycles K of 1051 and 1052.

FIG. 13 is a drawing illustrating waveforms of an analog test signal V(t) that contains a fundamental wave only, an analog test signal V′(t) that contains the fundamental wave and a third harmonic, and an analog test signal V″(t) that contains the fundamental wave, the third harmonic, and a fifth harmonic;

FIG. 14 is a drawing illustrating histograms corresponded to the analog test signals V(t), V′(t), and V″(t);

FIG. 15 is a drawing illustrating histograms corresponded to the analog test signals V(t), V′(t), and V″(t); and

FIG. 16 is a block diagram illustrating a waveform generator structured to generate the analog test signal V″(t).

### DETAILED DESCRIPTION

### Outline of Embodiments

Some exemplary embodiments of the present disclosure will be outlined. This outline is intended for briefing some concepts of one or more embodiments for the purpose of basic understanding of the embodiments as an introduction before detailed description that follows, without limiting the scope of the invention or disclosure. This outline is not an extensive overview of all possible embodiments and is therefore intended neither to specify key elements of all embodiments, nor to delineate the scope of some or all of the embodiments. For convenience, the term “one embodiment” may be used to designate one embodiment (example or modified example), or a plurality of embodiments (examples or modified examples) disclosed in the present specification.

A testing apparatus according to one embodiment is structured to test a semiconductor device having an A/D converter. The testing apparatus has a waveform generator structured to supply an analog test signal that contains a sine wave with a cycle of T, to the A/D converter; a waveform acquisition unit structured to store a group of output codes generated by the A/D converter, over a period with an integer K multiple duration of the cycle T, in response to the analog test signal; and an evaluation device structured to generate a histogram of the group of output codes stored by the waveform acquisition unit, and to evaluate the A/D converter on the basis of the histogram.

With the output codes of the A/D converter captured just across the integer number of cycles K of the sine wave, it becomes no longer necessary to consider the frequency of the sine wave, thus simplifying an equation for estimating a cumulative probability density of the sine wave.

In one embodiment, the integer K may be a prime number. With the number of cycles K defined as a prime number, it now becomes possible to largely reduce variation in the histogram among the codes.

Letting the count of a certain code i be P_{[i]}, the evaluation device in one embodiment may acquire a count P_{[x]} of a minimum code x and a count P_{[y]} of a maximum code y, and if P_{[x]}>P_{[y]}, may detect a code z which gives an integrated value, over a section ranging from z to y in the histogram, closest to P_{[x]}, and may determine a midpoint between x and z as an offset q of the sine wave. This enables acquisition of more accurate offset, as compared with a case where a code whose count becomes lowest around the center of the histogram is defined as the offset.

Letting the count of a certain code i be P_{[i]}, the evaluation device in one embodiment may acquire a count P_{[x]} of a minimum code x and a count P_{[y]} of a maximum code y, and if P_{[x]}<P_{[y]}, may detect a code z which gives an integrated value, over a section ranging from x to z in the histogram, closest to P_{[y]}, and may determine a midpoint between z and y as an offset q of the sine wave. This enables acquisition of more accurate offset, as compared with a case where a code whose count becomes lowest around the center of the histogram is defined as the offset.

With the offset of the sine wave given by q, the evaluation device in one embodiment may estimate an amplitude p of the sine wave, with use of a code j that satisfies x<j<y, and the count P_{[j]} thereof, according to an equation below:

p=√{(N/π·P_{[j]})²+(j−q)²}.

This enables accurate detection of the amplitude p.

The evaluation device in one embodiment may estimate values of amplitude p for a plurality of different codes j, and may average the plurality of values of amplitude p.

In one embodiment, the number of cycles K may be determined so that a minimum non-zero count of the histogram will be 10 or larger.

The testing apparatus according to one embodiment has: a waveform generator structured to supply a periodic analog test signal that contains a sine wave to the A/D converter; a waveform acquisition unit structured to store a group of output codes generated by the A/D converter, over a period with an integer K multiple duration of the cycle of the analog test signal, in response to the analog test signal; and an evaluation device structured to generate a histogram of the group of the output codes acquired by the waveform acquisition unit, and to evaluate the A/D converter on the basis of the histogram. Letting the count of a certain code i be P_{[i]}, the evaluation device is structured to acquire a count P_{[x]} of a minimum code x and a count P_{[y]} of a maximum code y, to detect, if P_{[x]}>P_{[y]}, a code z which gives an integrated value, over a section ranging from z to y in the histogram, closest to P_{[x]}, and to determine a midpoint between x and z as an offset q of the sine wave.

Letting the count of a certain code i be P_{[i]}, the evaluation device in one embodiment may acquire a count P_{[x]} of a minimum code x and a count P_{[y]} of a maximum code y, and if P_{[x]}<P_{[y]}, may detect a code z which gives an integrated value, over a section ranging from x to z in the histogram, closest to P_{[y]}, and may determine a midpoint between z and y as an offset q of the sine wave.

### Embodiments

The present invention will be explained below on the basis of preferred embodiments, referring to the attached drawings. All similar or equivalent constituents, members and processes illustrated in the individual drawings will be given same reference numerals, so as to properly avoid redundant explanations. The embodiments are merely illustrative, and are not restrictive about the invention. All features and combinations thereof described in the embodiments are not always necessarily essential to the present invention.

In the present specification, a “state in which member A is connected to member B” includes a case where the member A and the member B are physically and directly connected, and a case where the member A and the member B are indirectly connected via some other member that does not substantially affect the electrical connection state between the members A and B, or does not degrade the function or effect demonstrated by the coupling thereof.

Similarly, a “state in which member C is provided between member A and member B” includes a case where the member A and the member C, or the member B and the member C are directly connected, and a case where they are indirectly connected, while placing in between some other member that does not substantially affect the electrical connection state among the members, or does not degrade the function or effect demonstrated by the members.

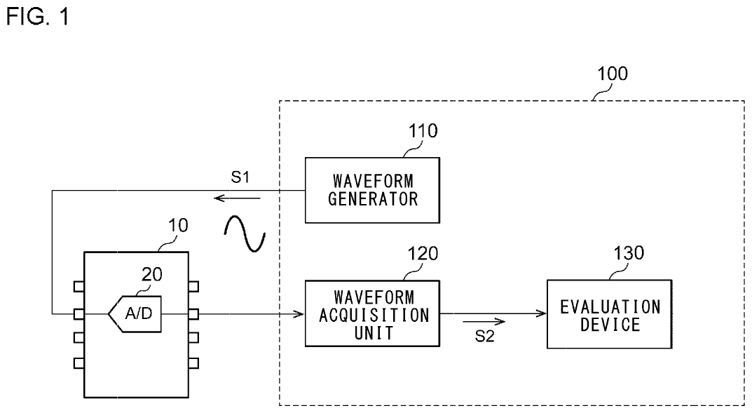

FIG. 1 is a block diagram illustrating a testing apparatus 100 of an embodiment. The test device 100 is structured to test a semiconductor device (DUT: Device Under Test) 10.

The DUT 10 has an A/D converter 20. The DUT 10, although the type thereof is not specifically limited, may typically be a front end circuit that converts an output for a sensor to a digital signal. The sensor is exemplified by thermocouple, thermistor, and resistance temperature detector (RTD).

A waveform generator 110 supplies a periodic analog test signal S1 to the A/D converter 20. The waveform generator 110 may have a waveform table that holds waveform data, a D/A converter that converts data read from the waveform table to an analog signal, and a low-pass filter that removes a high-frequency component from an output of the D/A converter. In the present embodiment, the analog test signal S1 is a sine wave.

A waveform acquisition unit 120 stores a group of output codes generated by the A/D converter 20, just over a period with an integer K multiple duration of the cycle of the sine wave, in response to the analog test signal S1.

Let the sampling rate of the A/D converter 20 be fs, and the frequency of the sine wave be f₀. Now, the waveform acquisition unit 120 stores a group S2 (referred to as an output code group) of output codes whose quantity is given by N=K×fs/f₀.

An evaluation device 130 generates a histogram of the stored output code group S2 stored by the waveform acquisition unit 120 and evaluates the A/D converter 20 on the basis of the histogram.

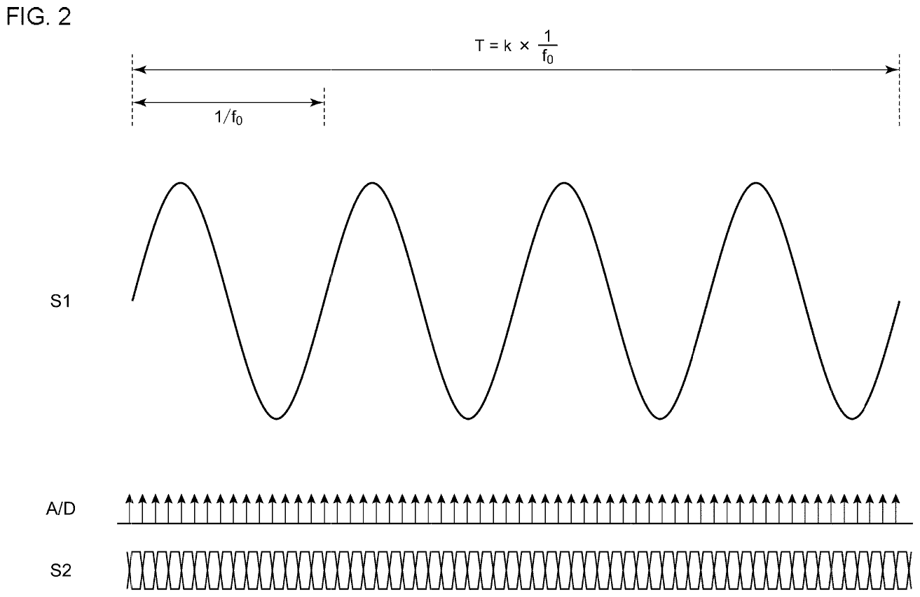

The structure of the testing apparatus 100 has been described. Next, the operations thereof will be explained. FIG. 2 is a drawing explaining a test of the A/D converter 20 with use of the testing apparatus 100 illustrated in FIG. 1. FIG. 2 illustrates a case where the waveform is captured over a period T given by T=1/f₀×4, with K=4. A sinusoidal analog test signal S1 is sampled for each time of sampling, and converted to a digital code. The codes for four cycles are stored as an output code group S2.

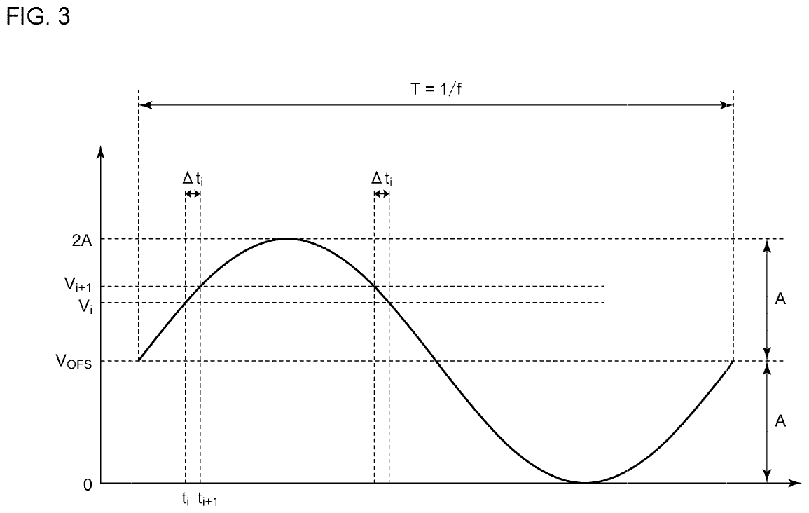

FIG. 3 is a drawing illustrating a sine wave. Assume now a sine wave with an angular frequency ω, an amplitude A, and a DC level (offset) of V_{OFS}.

V(t)=A sin ωt+V_{OFS} (1)

In a case, as described previously, where the analog test signal S1 is sampled over a period with an integer multiple duration of the cycle of the sine wave, it is no longer necessary to consider the angular frequency ω, instead the angular frequency ω, given by ω=2πf, can be handled as 2π while normalizing f to 1.

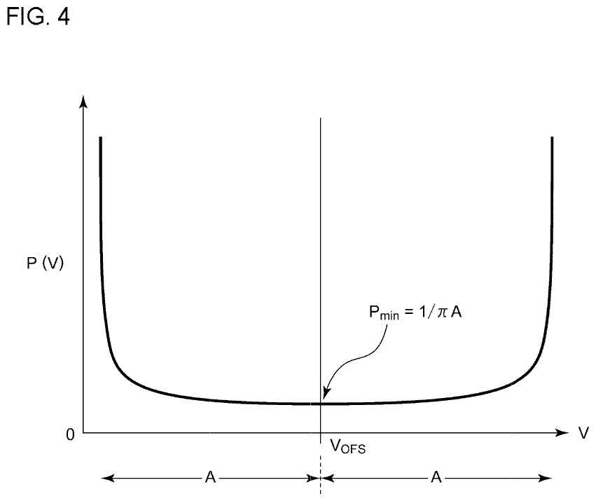

FIG. 4 is a drawing illustrating an amplitude probability density function p(V) of the sine wave illustrated in FIG. 3. The amplitude probability density function p(V) represents probability that the sine wave will have a certain value V, and is given by equation (2).

p(V)=1/{π√(A²−(V−V_{OFS})²)} (2)

The amplitude probability density p(V) will have a minimum value p_{MIN}=1/πA, when V=V_{OFS}.

The sine wave is discretized by the A/D converter, with use of Vᵢ (i=0, 1, . . . ) as a threshold value, and converted to a code. The histogram, if statistically significant, asymptotically approaches a product of the discretized amplitude probability density p(V) and the number of samples N, which is given by equation (3). P_{[i]} represents the count of the code i that corresponds to Vᵢ.

P_{[i]}=N×1/{π√(A²−(Vᵢ−V_{OFS})²)} (3)

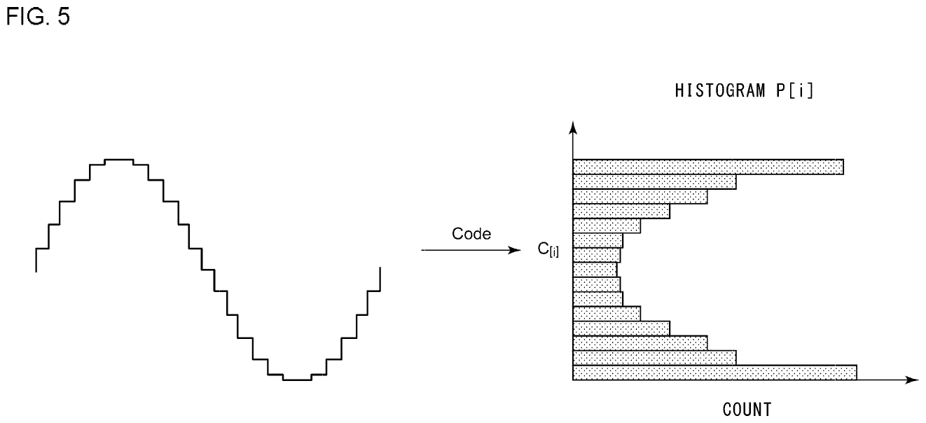

FIG. 5 is a drawing illustrating a relationship between a sine wave and a histogram. The number of sample data N may be determined so that the minimum count P_{MIN} will be larger than a predetermined value B, in order to make the histogram significant.

P_{MIN}=N×p_{MIN}=N/πA>B

B is preferably set, for example, around 10.

Let 2A=1 for normalization, then p_{MIN}=2/π holds. Setting m for the number of bits of the A/D converter 20, a theoretical count at the center of the histogram will be N/2^{m}×2/π, then it suffices to satisfy N/2^{m}×2/π≥B. Assuming a 16-bit A/D converter 20,

N/2¹⁶×2/π≥B

holds, then the number of sample data N is given by

N≥2¹⁶×π/2×B.

Assuming B=10, then obtainable is

N≥1029438.

The number of sample data N is more conveniently a squared value. Let π×B=32, it suffices to satisfy

N≥2^{m}×32/2=2^{(m+4)}.

Assuming

N=2^{(m+L)}

with L≥4, then the number of sample data N may be given by a squared value, making the minimum frequency P_{MIN} larger than 10. The number of sample data N with L=4 is given as

N=1048576.

With the sampling rate of the A/D converter 20 given as 1 Msps, the test time T will be T=1048576/1 Msps=1.048576 seconds, which is approximated to 1 second, and is practical enough.

As described above, a duration over which the A/D converter 20 generates N pieces of code necessarily contains just an integer K multiple of cycles of the sine wave. For example, consider a case where the frequency f₀ of the analog test signal S1 is around 1 kHz. The test time T and the frequency f₀ may only satisfy a relation

T=K/f₀.

Given T=1.048576 and K=1050, then

f=K/T=1001.35803222656Hz

will suffice.

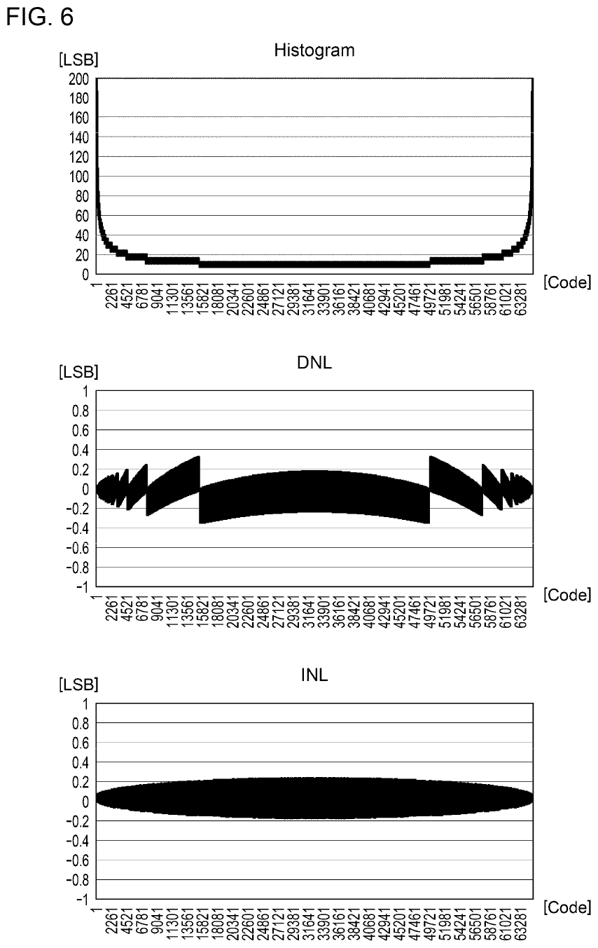

FIG. 6 is a drawing illustrating results of simulation of the histogram, DNL, and INL. A known technique is applicable to estimate DNL and INL from the histogram. For example, DNL and INL may be estimated from a cumulative probability density PIⱼ having been estimated over a range from code 0 to code j.

Ideally, the sinusoidal analog test signal is preferably varied over the full scale range of the A/D converter 20 to be tested. The range of the analog test signal S1, however, does not always coincide with the full scale range of the A/D converter 20, due to the offset of the A/D converter 20, variation in the center level V_{OFS} of the analog test signal S1, and variation in the amplitude A of the analog test signal S1.

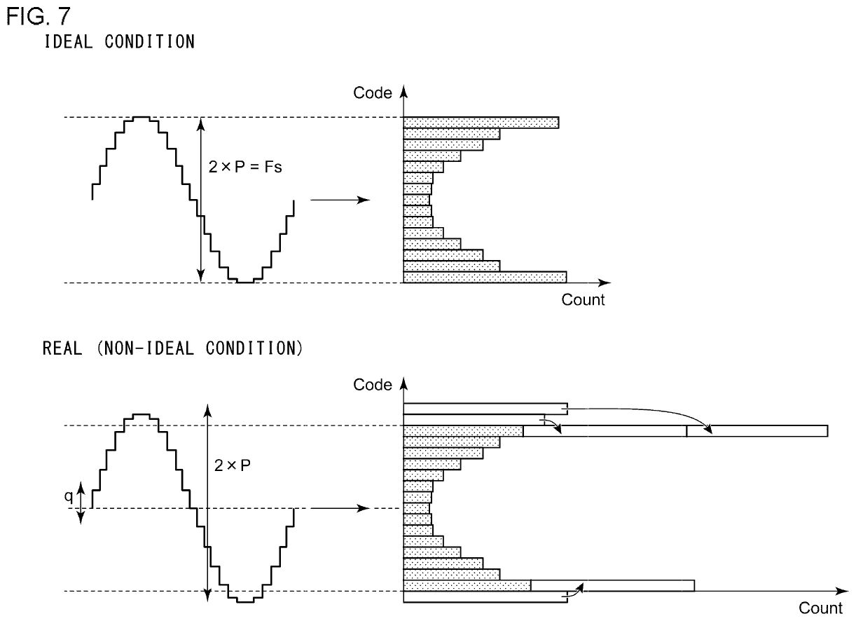

FIG. 7 is a drawing illustrating relationships between the full scale FS of the A/D converter and voltage levels of the analog test signals S1. The upper tier of FIG. 7 illustrates a histogram obtained under an ideal condition, and the lower tier of FIG. 7 illustrates a histogram under a non-ideal condition, which is more specifically a case where the analog test signal S1 exceeds the full scale FS of the A/D converter. Disagreement between the analog test signal S1 and the full scale FS makes the amplitude probability density distribution deviate from that of the sine wave, and creates asymmetry in the histogram.

A method for estimating the offset and the amplitude of the sine wave under the non-ideal condition will be described.

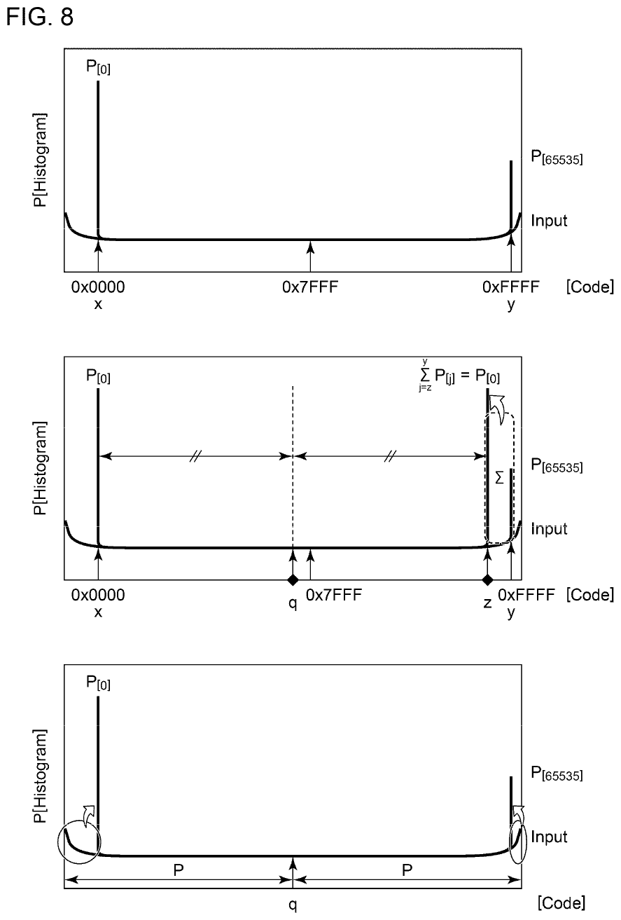

FIG. 8 is a drawing illustrating histograms obtainable under the non-ideal condition. The top diagram is a histogram obtained by the measurement. Let the count of a certain code i be P_{[i]}. A 16 bit A/D converter takes the codes ranged from 0x0000 to 0xFFFF in hexadecimal notation, and from 0 to 65535 in decimal notation.

The evaluation device 130 acquires the count P_{[x]} of the minimum code x, and the count P_{[y]} of the maximum code y. In the exemplary case of FIG. 8, the minimum code x is 0, and the maximum code y is 65535.

A relationship P_{[0]}>P_{[65535]} holds between the count P_{[0]} of the minimum code x and the count P_{[65535]} of the maximum code y.

The evaluation device 130 detects code z which gives an integrated value Σ_{j=z:y}P_{[j]} over the section ranging from z to y of the histogram closest to P_{[x]}.

Σ_{j=z:y}P_{[j]}≈P_{[0]}

Then, a midpoint between x and z is defined as an offset (DC level) q of the sine wave.

q=(x+z)/2

On the contrary, if P_{[x]}<P_{[y]}, the evaluation device 130 detects code z which gives an integrated value Σ_{j=x:z}P_{[j]} over the section ranging from x to z of the histogram closest to P_{[y]}. Then, a midpoint between z and y is defined as an offset q of the sine wave.

q=(z+y)/2

Next, estimation of the amplitude p of the sine wave will be described. The evaluation device 130 uses the thus obtained offset q to estimate the amplitude p of the sine wave, according to the equation below.

p=√{(N/π·P_{[j]})²+(j−q)²}

j Is freely selectable from the codes in the histogram. For example, j=x, or j=y is applicable.

The evaluation device 130 may preferably estimate the amplitude p for a plurality of different codes j, and then average the plurality of amplitudes p obtained for the plurality of codes j. For example, the amplitudes pₓ and p_{y} may be estimated for two points, j=x (=0) and j=y (=65535), and may be averaged to yield the amplitude p.

For verification, consider a sine wave with amplitude p=32790, and offset q=32757. This sine wave varies within the range from −33 to 66547. Given N=1048576, then P_{[0]}=15090 and P_{[65534]}=9218 hold. Now, z is 65513. The midpoint between x and z is therefore given by 65513/2=32756.5, which substantially coincides with the initially determined offset q=32757.

An estimated value p\hat{ }of the amplitude p for j=1 is 32789.37, and an estimated value p\hat{ } of the amplitude p for j=65534 is 32790.61. An average value of the two estimated values p\hat{ } of the amplitude is given by p′=32789.99, which also substantially coincides with the initially defined amplitude p=32790.

As described above, the present embodiment can exactly detect the offset q and the amplitude p of the sine wave, on the basis of the histogram, even by the test under the non-ideal condition.

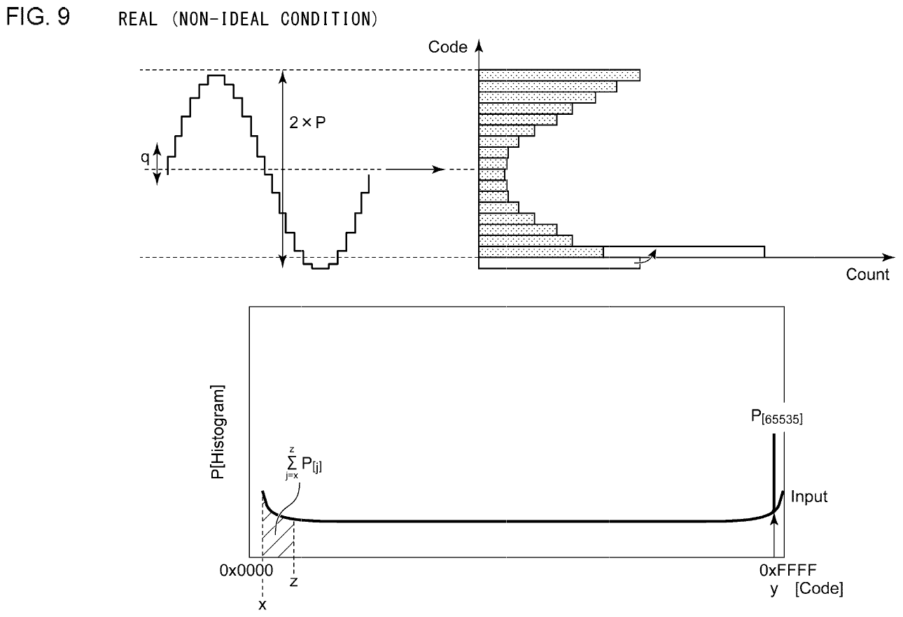

The sine wave, although illustrated in FIG. 8 as exceeding both of the minimum value 0 and the maximum value 65535 that define the full scale, is not limited thereto, instead allowing excess only either of them. FIG. 9 is a drawing illustrating a histogram obtainable under another non-ideal condition. Also in this example, the count P_{[x]} of the minimum code x (=0), and the count P_{[y]} of the maximum code y (=65535) are acquired. If P_{[x]}<P_{[y]}, the evaluation device 130 detects code z which gives an integrated value Σ_{j=x:z}P_{[j]} over the section ranging from x to z of the histogram closest to P_{[y]}. Then, a midpoint between z and y is defined as an offset q of the sine wave.

As described above, the measurement period over which the output codes of the A/D converter 20 are stored was defined by a duration that corresponds to an integer K multiple of the cycles of the sine wave. The present inventors have recognized that choice of a prime number as the number of cycles K could largely improve the measurement accuracy.

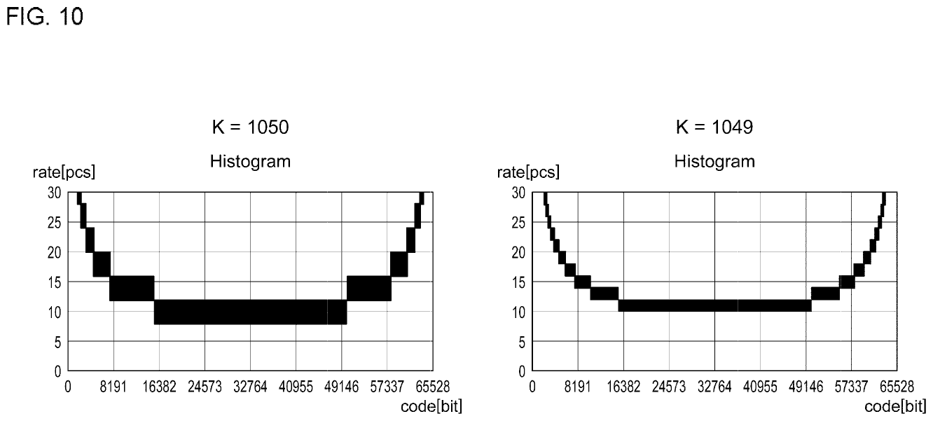

FIG. 10 is a drawing illustrating histograms obtainable at the numbers of cycles K of 1050 and 1049. An integer K of 1050, which is a non-prime number, yields an inter-code variation in the count of 4, meanwhile an integer K of 1049, which is a prime number, yields an inter-code variation in the count of 2. The inter-code variation in the count largely affects the accuracy of DNL and INL.

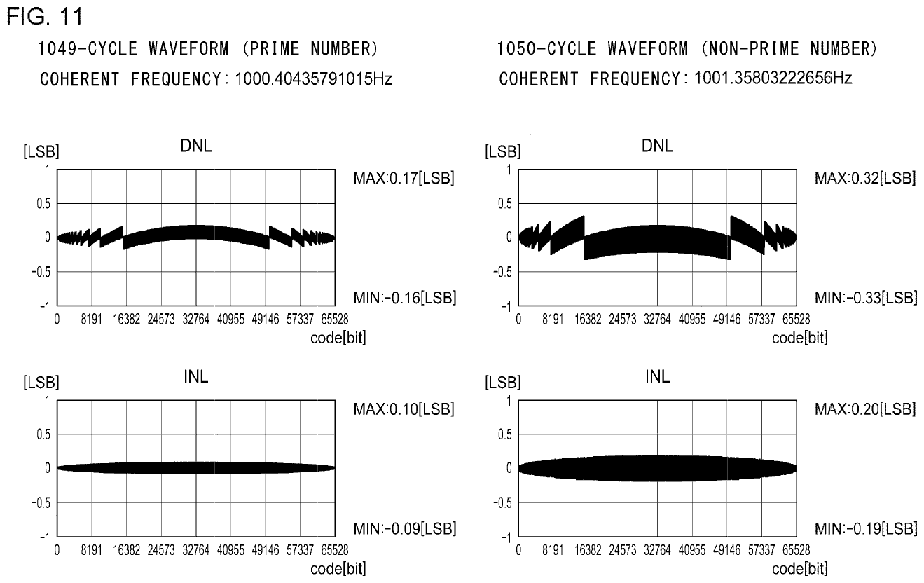

FIG. 11 is a drawing illustrating theoretical DNL and INL at the numbers of cycles K of 1049 and 1050. Comparison between the two teaches that the theoretical INL and DNL become smaller by a choice of prime number 1049. That is, estimation accuracy of DNL and INL when the real A/D converter is measured may be improved.

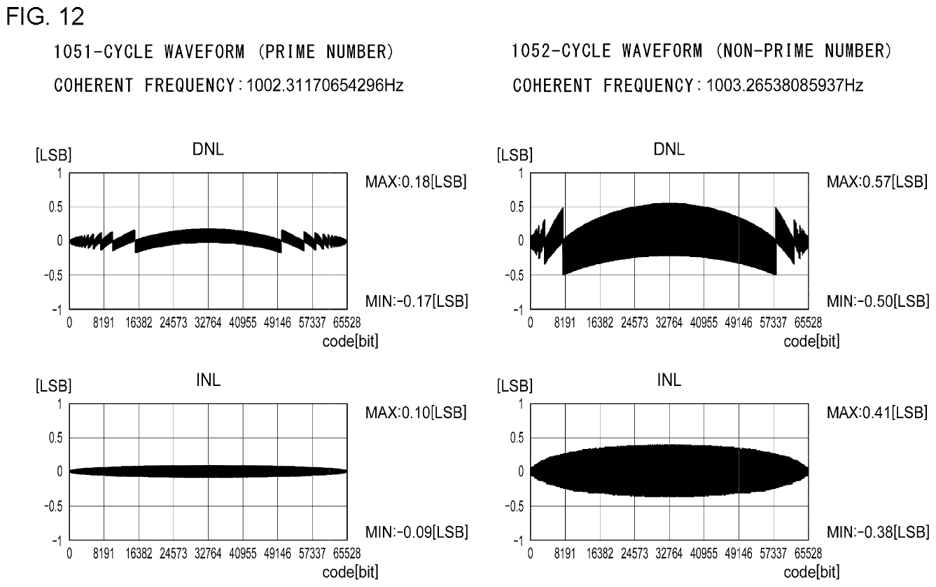

FIG. 12 is a drawing illustrating theoretical DNL and INL at the numbers of cycles K of 1051 and 1052. Comparison between the two teaches that the theoretical INL and DNL become smaller by a choice of prime number 1051. That is, estimation accuracy of DNL and INL when the real A/D converter is measured may be improved.

Note that the method of estimating the offset q and the amplitude p of the sine wave, described with reference to FIG. 8, is also applicable to a case where the analog test signal has any selectable number of cycles.

### Correction of Analog Test Signal

The aforementioned embodiment has used the single-frequency (monotone) sine wave as illustrated in FIG. 3, as the analog test signal. Since the waveform of the sine wave has a most steep slope around the DC level V_{OFS}, so that the amplitude probability density function p(V) illustrated in FIG. 4 gives the minimum value Pmin at the DC level V_{OFS}. The larger the minimum value Pmin, the higher the accuracy, or the shorter the test time required to achieve the same estimation accuracy, and this only needs reduction of the slope of the analog test signal S1 around the DC.

A corrected analog test signal contains odd-order harmonics with a waveform close to a triangular wave. More specifically, an analog test signal V′(t) that contains the fundamental wave and a third harmonic is expressed by equation (4).

V′(t)=A(sin ωt−1/9 sin 3ωt)+V_{OFS} (4)

An analog test signal V′(t) that contains the fundamental wave, the third harmonic, and a fifth harmonic is expressed by equation (5).

V″(t)=A(sin ωt−1/9 sin 3ωt+1/25 sin 5ωt)+V_{OFS} (5)

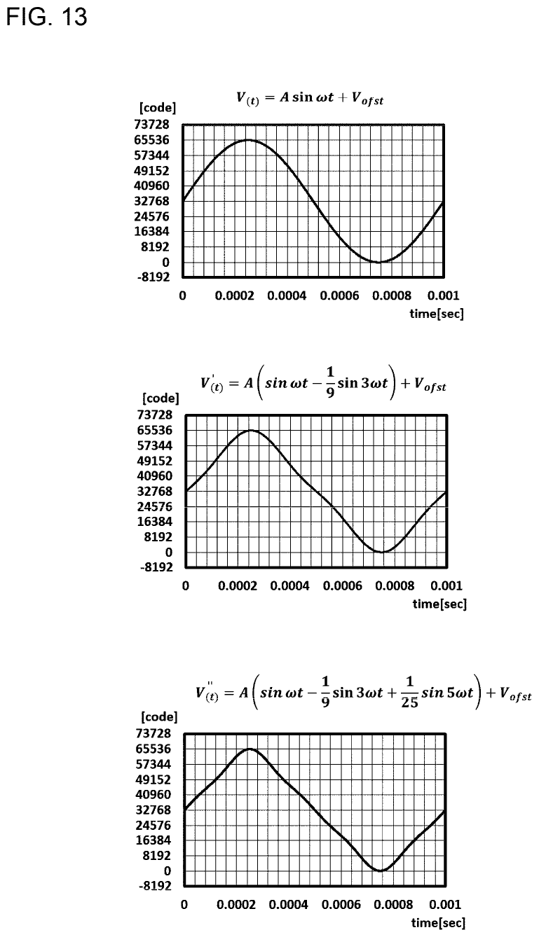

FIG. 13 is a drawing illustrating waveforms of the analog test signal V(t) that contains the fundamental wave only, the analog test signal V′(t) that contains the fundamental wave and the third harmonic, and the analog test signal V″(t) that contains the fundamental wave, the third harmonic, and the fifth harmonic.

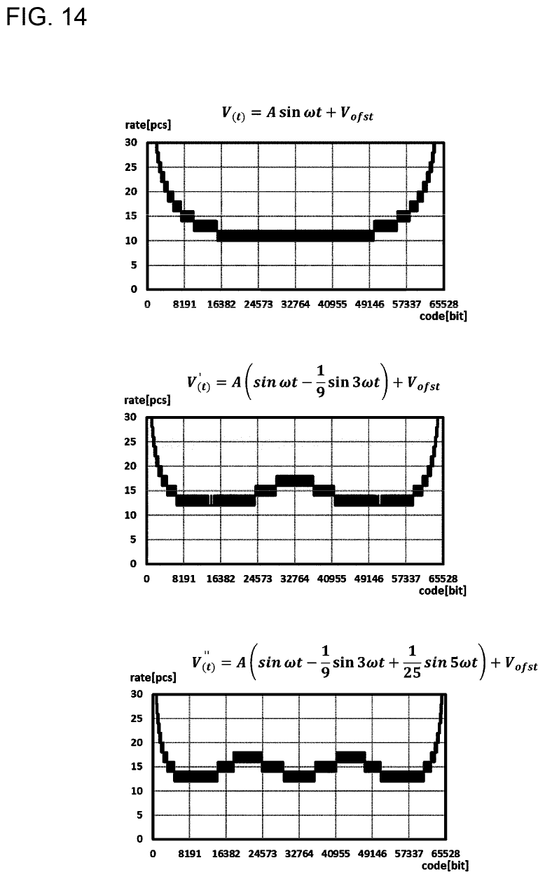

FIG. 14 is a drawing illustrating histograms corresponded to the analog test signals V(t), V′(t), and V″(t). Given a frequency of the analog test signal of 1000.40435791015 Hz, and K=1049, each histogram plots 1048576 points obtained over one second.

The analog test signal V(t) gives a minimum frequency of 10 for code 32764 in the histogram, whereas the analog test signals V′(t) and V″(t) give the minimum frequency increased up to 12. This means that the estimation accuracy may be improved by 20%.

The results illustrated in FIG. 14 also suggest that the same level of estimation accuracy is obtainable within a test time shortened by 20%.

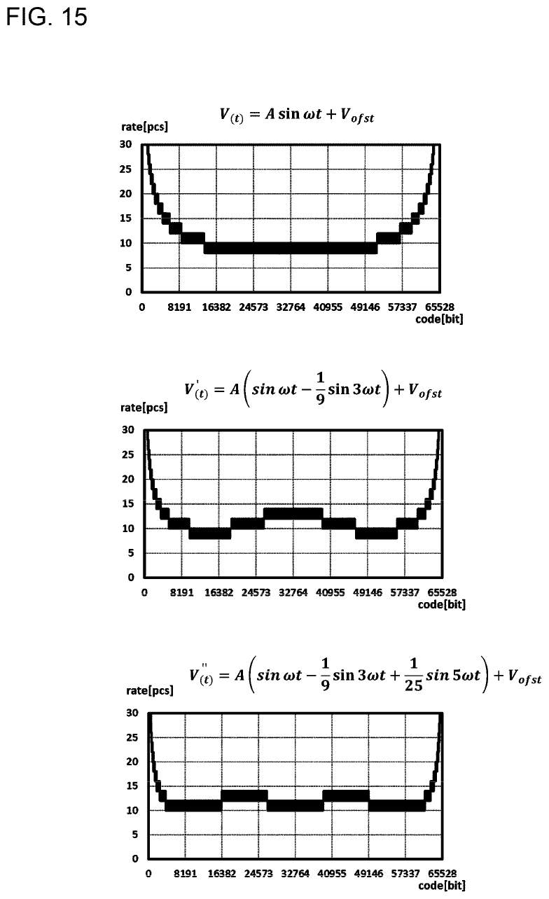

FIG. 15 is a drawing illustrating histograms corresponded to the analog test signals V(t), V′(t), and V″(t). Given a frequency of the analog test signal of 1000.16689316453 Hz, and K=839, each histogram plots 838860 points obtained over 0.8 seconds.

The minimum frequency of the analog test signal V(t) for code 32764 in the histogram decreases from 10 to 8, since the number of points reduces by 20% as compared with the example of FIG. 14. In this example, also the analog test signal V′(t) gives the minimum frequency for code 32764 in the histogram reduced down to 8, proving no superiority over V(t). On the other hand, V″(t) that contains up to the fifth harmonic gives a minimum frequency of 10, proving that the minimum frequency same as that in a case where the sine wave V(t) is used is obtainable within a measurement time of 0.8 seconds. That is, the same level of estimation accuracy was confirmed to be obtainable within a test time shortened by 20%.

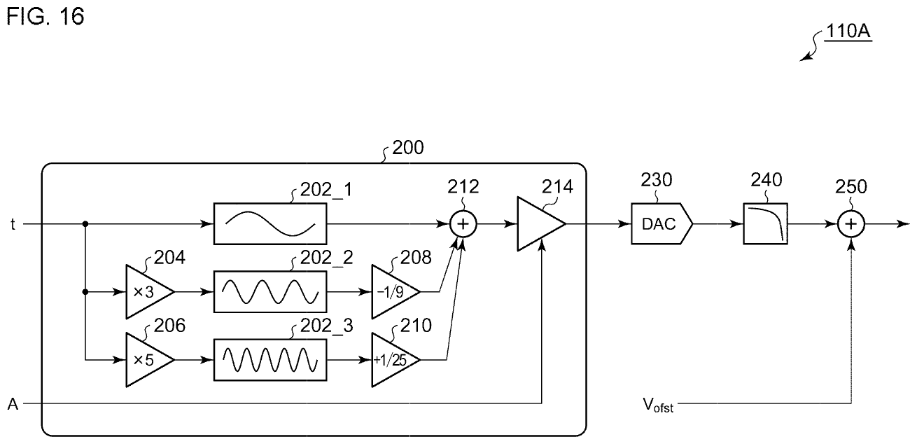

FIG. 16 is a block diagram illustrating a waveform generator 110A structured to generate the analog test signal V″(t). The waveform generator 110A has a digital waveform generator 200, a D/A converter 230, a low-pass filter 240, and an analog adder 250.

The digital waveform generator 200 may be constituted typically by a field programmable gate array (FPGA). Each of the sine modulators 202_1 to 202_3 outputs a sine wave Sin(a) in response to input “a”. The sine modulator 202_1 has an input of a digital value corresponded to time ωt, and therefore outputs sin(ωt). A multiplier 204 multiplies the digital value corresponded to time ωt by three, and inputs the product to the sine modulator 202_2. The sine modulator 202_2 outputs sin(3ωt). A multiplier 206 multiplies the digital value corresponded to time ωt by five, and inputs the product to the sine modulator 202_3. The sine modulator 202_3 outputs sin(5ωt).

A multiplier 208 multiplies sin(3ωt), which is the output of the sine modulator 202_2, by a coefficient of −1/9. A multiplier 210 multiplies sin(5ωt), which is the output of the sine modulator 202_3, by a coefficient of 1/25. An adder 212 adds output sin(ωt) of the sine modulator 202_1, output−1/9 ·sin(3ωt) of the multiplier 208, and output 1/25 ·sin(5ωt) of the multiplier 210. A multiplier 214 multiplies an output of the adder 212 by a coefficient A that corresponds to the amplitude.

The D/A converter 230 converts the output of the digital waveform generator 200 to an analog voltage. The low-pass filter 240 removes a high-frequency component from the output of the analog voltage. A cutoff frequency of the low-pass filter 240 is set higher than 5ω. The analog adder 250 adds the offset voltage Vofs to the output signal of the low-pass filter 240.

The embodiments merely illustrate an aspect of the principle and applications of the present disclosure, allowing a variety of modifications and layout changes without departing from the spirit of the present invention specified by the claims.

### Supplement

The following techniques are disclosed herein.

### Item 1

A testing apparatus for testing a semiconductor device having an A/D converter, the testing apparatus comprising:

a waveform generator structured to supply an analog test signal that contains a sine wave with a cycle of T, to the A/D converter;

a waveform acquisition unit structured to store a group of output codes generated by the A/D converter, over a period with an integer K multiple duration of the cycle T, in response to the analog test signal; and

an evaluation device structured to generate a histogram of the group of output codes stored by the waveform acquisition unit, and to evaluate the A/D converter on the basis of the histogram.

### Item 2

The testing apparatus according to item 1, wherein the integer K is a prime number.

### Item 3

The testing apparatus according to item 1 or 2, wherein, letting a count of a certain code i be P_{[i]}, the evaluation device is structured to acquire a count P_{[x]} of a minimum code x and a count P_{[y]} of a maximum code y,

to detect, if P_{[x]}>P_{[y]}, a code z which gives an integrated value, over a section ranging from z to y in the histogram, closest to P_{[x]}, and

to determine a midpoint between x and z as an offset q of the sine wave.

### Item 4

The testing apparatus according to item 1 or 2, wherein, letting a count of a certain code i be P_{[i]},

the evaluation device is structured to acquire a count P_{[x]} of a minimum code x and a count P_{[y]} of a maximum code y,

to detect, if P_{[x]}<P_{[y]}, a code z which gives an integrated value, over a section ranging from x to z in the histogram, closest to P_{[y]}, and

to determine a midpoint between z and y as an offset q of the sine wave.

### Item 5

The testing apparatus according to item 1 or 2, wherein, with the offset of the sine wave given by q, the evaluation device is structured to estimate an amplitude p of the sine wave, with use of a code j that satisfies x<j<y, and the count P_{[j]} thereof, according to an equation below:

p=√{(N/π·P_{[j]})²+(j−q)²}.

### Item 6

The testing apparatus according to item 5, wherein the evaluation device is structured to estimate values of amplitude p for a plurality of different codes j, and to average the plurality of values of amplitude p.

### Item 7

The testing apparatus according to item 1 or 2, wherein the integer K is determined so that a minimum non-zero count of the histogram will be 10 or larger.

### Item 8

The testing apparatus according to item 1 or 2, wherein the analog test signal further contains a third harmonic of the sine wave, and is given by

A(sin ωt−1/9×sin 3ωt)+Vofs,

wherein

A represents amplitude;

ω represents angular frequency; and

Vofs represents offset.

### Item 9

The testing apparatus according to item 8, wherein the analog test signal further contains a fifth harmonic of the sine wave, and is given by

A(sin ωt−1/9×sin 3ωt+1/25×sin 5ωt)+Vofs.

### Item 10

A testing apparatus for testing a semiconductor device having an A/D converter, the testing apparatus comprising:

a waveform generator structured to supply a periodic analog test signal that contains a sine wave to the A/D converter;

a waveform acquisition unit structured to store a group of output codes generated by the A/D converter, over a period with an integer K multiple duration of the cycle of the analog test signal, in response to the analog test signal; and

an evaluation device structured to generate a histogram of the group of the output codes acquired by the waveform acquisition unit, and to evaluate the A/D converter on the basis of the histogram,

letting an i-th code be C_{[i]}, and letting the count thereof be P_{[i]}, the evaluation device being structured to acquire a count P_{[x]} of a minimum code x and a count P_{[y]} of a maximum code y,

to detect, if P_{[x]}>P_{[y]}, a code z which gives an integrated value, over a section ranging from z to y in the histogram, closest to P_{[x]}, and

to determine a midpoint between x and z as an offset q of the sine wave.

### Item 11

The testing apparatus according to item 10, wherein, letting a count of a certain code i be P_{[i]},

the evaluation device is structured to acquire a count P_{[x]} of a minimum code x and a count P_{[y]} of a maximum code y,

to detect, if P_{[x]}<P_{[y]}, a code z which gives an integrated value, over a section ranging from x to z in the histogram, closest to P_{[y]}, and to determine a midpoint between z and y as an offset q of the sine wave.

### Item 12

A testing method for testing a semiconductor device having an A/D converter, the method comprising:

supplying an analog test signal that contains a sine wave and a cycle T, to the A/D converter;

storing a group of output codes generated by the A/D converter, over a period with an integer K multiple duration of the cycle T, in response to the analog test signal; and

generating a histogram of the stored group of output codes and evaluating the A/D converter on the basis of the histogram.

### Item 13

The testing method according to item 12, wherein the integer K is a prime number.

### Item 14

The testing method according to item 12 or 13, wherein the analog test signal further contains a third harmonic of the sine wave, and is given by

A(sin ωt−1/9×sin 3ωt)+Vofs,

wherein

A represents amplitude;

ω represents angular frequency; and

Vofs represents offset.

### Item 15

The testing method according to item 14, wherein the analog test signal further contains a fifth harmonic of the sine wave, and is given by

A(sin ωt−1/9×sin 3ωt+1/25×sin 5ωt)+Vofs.

### Item 16

The testing method according to item 12 or 13, wherein, letting a count of a certain code i be P_{[i]},

the evaluation step is structured to acquire a count P_{[x]} of a minimum code x and a count P_{[y]} of a maximum code y,

to detect, if P_{[x]}>P_{[y]}, a code z which gives an integrated value, over a section ranging from z to y in the histogram, closest to P_{[x]}, and

to determine a midpoint between x and z as an offset q of the sine wave.

### Item 17

The testing method according to item 12 or 13, wherein, letting a count of a certain code i be P_{[i]},

the evaluation step is structured to acquire a count P_{[x]} of a minimum code x and a count P_{[y]} of a maximum code y,

to detect, if P_{[x]}<P_{[y]}, a code z which gives an integrated value, over a section ranging from x to z in the histogram, closest to P_{[y]}, and

to determine a midpoint between z and y as an offset q of the sine wave.

### Item 18

The testing method according to item 12 or 13, wherein, with the offset of the sine wave given by q, the evaluation step is structured to estimate an amplitude p of the sine wave, with use of a code j that satisfies x<j<y, and the count P_{[j]} thereof, according to an equation below:

p=√{(N/π·P_{[j]})²+(j−q)²}.

### Item 19

The testing method according to item 18, wherein the evaluation step is structured to estimate values of amplitude p for a plurality of different codes j, and to average the plurality of values of amplitude p.

### Item 20

A testing method for testing a semiconductor device having an A/D converter, the testing method comprising:

supplying a periodic analog test signal that contains a sine wave to the A/D converter;

storing a group of output codes generated by the A/D converter, over a period with an integer K multiple duration of the cycle of the analog test signal, in response to the analog test signal; and

generating a histogram of the stored group of output codes, and evaluating the A/D converter on the basis of the histogram,

letting the count of a certain code i be P_{[i]}, the evaluation step being structured to acquire a count P_{[x]} of a minimum code x and a count P_{[y]} of a maximum code y,

to detect, if P_{[x]}>P_{[y]}, a code z which gives an integrated value, over a section ranging from z to y in the histogram, closest to P_{[x]}, and

to determine a midpoint between x and z as an offset q of the sine wave.

### Item 21

The testing method according to item 20, wherein, letting a count of a certain code i be P_{[i]},

the evaluation step is structured to acquire a count P_{[x]} of a minimum code x and a count P_{[y]} of a maximum code y,

to detect, if P_{[x]}<P_{[y]}, a code z which gives an integrated value, over a section ranging from x to z in the histogram, closest to P_{[y]}, and

to determine a midpoint between z and y as an offset q of the sine wave.

What is claimed is:

1. A testing apparatus for testing a semiconductor device having an A/D converter, the testing apparatus comprising:
a waveform generator structured to supply an analog test signal that contains a sine wave with a cycle of T, to the A/D converter;
a waveform acquisition unit structured to store a group of output codes which the A/D converter generates over a period with an integer K multiple duration of the cycle T in response to the analog test signal; and
an evaluation device structured to generate a histogram of the group of output codes stored by the waveform acquisition unit, and to evaluate the A/D converter on the basis of the histogram.

2. The testing apparatus according to claim 1, wherein the integer K is a prime number.

3. The testing apparatus according to claim 1, wherein, letting a count of a certain code be P_{[i]},
the evaluation device is structured to acquire a count P_{[x]} of a minimum code x and a count P_{[y]} of a maximum code y,
to detect, if P_{[x]}>P_{[y]}, a code z which gives an integrated value, over a section ranging from z to y in the histogram, closest to P_{[x]}, and
to determine a midpoint between x and z as an offset q of the sine wave.

4. The testing apparatus according to claim 1, wherein
letting a count of a certain code i be P_{[i]},
the evaluation device is structured to acquire a count P_{[x]} of a minimum code x and a count P_{[y]} of a maximum code y,
to detect, if P_{[x]}<P_{[y]}, a code z which gives an integrated value, over a section ranging from x to z in the histogram, closest to P_{[y]}, and
to determine a midpoint between z and y as an offset q of the sine wave.

5. The testing apparatus according to claim 1, wherein, with the offset of the sine wave given by q, the evaluation device is structured to estimate an amplitude p of the sine wave, with use of a code j that satisfies x<j<y, and the count P_{[j]} thereof, according to an equation below:
p=√{(N/π·P_{[j]})²+(j−q)²}.

6. The testing apparatus according to claim 5, wherein the evaluation device is structured to estimate values of amplitude p for a plurality of different codes j, and to average the plurality of values of amplitude p.

7. The testing apparatus according to claim 1, wherein the integer K is determined so that a minimum non-zero count of the histogram will be 10 or larger.

8. The testing apparatus according to claim 1, wherein the analog test signal further contains a third harmonic of the sine wave, and is given by
A(sin ωt−1/9×sin 3ωt)+Vofs,
wherein
A represents amplitude;
ω represents angular frequency; and
Vofs represents offset.

9. The testing apparatus according to claim 8, wherein the analog test signal further contains a fifth harmonic of the sine wave, and is given by
A(sin ωt−1/9×sin 3ωt+1/25×sin 5ωt)+Vofs.

10. A testing apparatus for testing a semiconductor device having an A/D converter, the testing apparatus comprising:
a waveform generator structured to supply a periodic analog test signal that contains a sine wave to the A/D converter;
a waveform acquisition unit structured to store a group of output codes which the A/D converter generates over a period with an integer K multiple duration of the cycle of the analog test signal in response to the analog test signal; and
an evaluation device structured to generate a histogram of the group of the output codes acquired by the waveform acquisition unit, and to evaluate the A/D converter on the basis of the histogram,
letting an i-th code be C_{[i]}, and letting the count thereof be P_{[i]},
the evaluation device being structured to acquire a count P_{[x]} of a minimum code x and a count P_{[y]} of a maximum code y,
to detect, if P_{[x]}>P_{[y]}, a code z which gives an integrated value, over a section ranging from z to y in the histogram, closest to P_{[x]}, and
to determine a midpoint between x and z as an offset q of the sine wave.

11. The testing apparatus according to claim 10, wherein, letting a count of a certain code i be P_{[i]},
the evaluation device is structured to acquire a count P_{[x]} of a minimum code x and a count P_{[y]} of a maximum code y,
to detect, if P_{[x]}<P_{[y]}, a code z which gives an integrated value, over a section ranging from x to z in the histogram, closest to P_{[y]}, and
to determine a midpoint between z and y as an offset q of the sine wave.

12. A testing method for testing a semiconductor device having an A/D converter, the method comprising:
supplying an analog test signal that contains a sine wave and a cycle T, to the A/D converter;
storing a group of output codes generated by the A/D converter, over a period with an integer K multiple duration of the cycle T, in response to the analog test signal; and
generating a histogram of the stored group of output codes and evaluating the A/D converter on the basis of the histogram.

13. The testing method according to claim 12, wherein the integer K is a prime number.

14. The testing method according to claim 12, wherein the analog test signal further contains a third harmonic of the sine wave, and is given by
A(sin ωt−1/9×sin 3ωt)+Vofs,
wherein
A represents amplitude;
ω represents angular frequency; and
Vofs represents offset.

15. The testing method according to claim 14, wherein the analog test signal further contains a fifth harmonic of the sine wave, and is given by
A(sin ωt−1/9×sin 3ωt+1/25×sin 5ωt)+Vofs.

16. The testing method according to claim 12, wherein
letting a count of a certain code i be P_{[i]},
the evaluation step is structured to acquire a count P_{[x]} of a minimum code x and a count P_{[y]} of a maximum code y,
to detect, if P_{[x]}>P_{[y]}, a code z which gives an integrated value, over a section ranging from z to y in the histogram, closest to P_{[x]}, and
to determine a midpoint between x and z as an offset q of the sine wave.

17. The testing method according to claim 12, wherein
letting a count of a certain code i be P_{[i]},
the evaluation step is structured to acquire a count P_{[x]} of a minimum code x and a count P_{[y]} of a maximum code y,
to detect, if P_{[x]}<P_{[y]}, a code z which gives an integrated value, over a section ranging from x to z in the histogram, closest to P_{[y]}, and
to determine a midpoint between z and y as an offset q of the sine wave.

18. The testing method according to claim 12, wherein, with the offset of the sine wave given by q, the evaluation step is structured to estimate an amplitude p of the sine wave, with use of a code j that satisfies x<j<y, and the count P_{[j]} thereof, according to an equation below:
p=√{(N/π·P_{[j]})²+(j−q)²}.

19. The testing method according to claim 18, wherein the evaluation step is structured to estimate values of amplitude p for a plurality of different codes j, and to average the plurality of values of amplitude p.
